(19) United States
(12) Patent Application Publication
(10) Pub. No.: US 2007/0249065 A1
(43) Pub. Date: Oct. 25, 2007

(54) Manufacturing method of semiconductor device

(75) Inventor: Mitsushi Fujiki, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/510,554

(22) Filed: Aug. 28, 2006

(30) Foreign Application Priority Data
Mar. 6, 2006 (JP) 2006-060152

(51) Int. Cl. H01L 21/00

(52) U.S. Cl. 438/3; 438/48

(57) ABSTRACT

After an interlayer insulating film and a lower side layer of a conductive film for a bottom electrode and the like are formed above a substrate, a Pt film of a thickness of 50 nm to 500 nm, for example, about 175 nm is formed on the lower side layer as an upper side layer of a conductive film for a bottom electrode by a DC magnetron sputtering method. As the lower side layer, for example, a Ti film is formed. A substrate temperature at a time of forming the upper side layer is set at 250° C. to 450° C., for example, at 350° C. By forming the upper side layer in such a substrate temperature, the upper side layer intense in orientation in a [222] direction is obtained. Therefore, orientation of a ferroelectric film which is formed directly thereon to a [111] direction also becomes extremely favorable.

### CROSS-REFERENCE TO RELATED APPLICATIONS

This application is based upon and claims the benefit of priority from the prior Japanese Patent Application No. 2006-060152, filed on Mar. 6, 2006, the entire contents of which are incorporated herein by reference.

### BACKGROUND OF THE INVENTION

1. Field of the Invention

The present invention relates to a manufacturing method of a semiconductor device including a ferroelectric capacitor.

2. Description of the Related Art

There are several types of nonvolatile memories retaining data even after power supply is turned off. Among them, an FeRAM (Ferroelectric Random Access Memory) especially attracts attention in recent years because of its high speed operation and low voltage operation.

An FeRAM includes a ferroelectric capacitor constructed by stacking a bottom electrode, a capacitor ferroelectric film and a top electrode in layer in this sequence, and stores data by causing two polarization directions of the capacitor ferroelectric film to correspond to “0” and “1”, respectively. Discrimination of “0” and “1” becomes easier as the polarization of the capacitor ferroelectric film is larger, and for this purpose, favorable crystallinity is required of the capacitor ferroelectric film.

As a capacitor ferroelectric film which is generally used, a PZT (Pb(Zrₓ,Ti₁₋ₓ)O₃) film is cited, and the PZT film polarizes in the [001] direction. Therefore, in the PZT film, spontaneous polarization can be maximized by aligning its orientation with the [901] direction. However, the orientation cannot be usually aligned with the [001] direction, and it is general to gain spontaneous polarization by aligning the orientation with the [111] direction instead.

The orientation of the PZT film is in the same direction as the orientation of the bottom electrode, and its orientation strength becomes larger as the orientation of the bottom electrode becomes stronger. Therefore, in order to make spontaneous polarization of the PZT film larger, it is suitable to compose the bottom electrode of a material which is strongly oriented in the same direction as the PZT [111], and a Pt film that is oriented in the [222] direction, which is the same direction as the [111] direction, is adopted as the bottom electrode.

However, when the Pt film is directly formed on an insulating film, the Pt film easily peels off from the insulating film. Thus, it is proposed to form a Pt film on an adhesive film such as a Ti (titanium) film and construct the bottom electrode by the Ti film and the Pt film as in Patent Document 1.

In this case, the orientation of the Ti film has an influence on the orientation of the Pt film thereon, and ultimately influences the orientation of the capacitor ferroelectric film, and therefore, it is desired to form a Ti film having strong orientation in the [002] direction.

For example, Non-patent Document 1 discloses the method for enhancing the orientation in the [002] direction of the Ti film by heating the substrate to 350° C., and doping H₂O in a sputtering atmosphere for Ti, and the experiment result.

Patent Document 1 also proposes a method for maximizing spontaneous polarization of the ferroelectric thin film by orienting the Pt film which becomes the base of a lead titanate ferroelectric thin film in the [200] direction and orienting the ferroelectric thin film thereon in a c-axis direction, which is the polarization direction thereof.

However, the method described in Patent Document 1 requires the complicated steps of (i) forming a Pt—Pb alloy thin film, (ii) oxidizing a Pt—Pb alloy thin film and (iii) removing a PbO layer formed by the oxidation, in order to orient the Pt film in the [200] direction. Therefore, the process of a FeRAM is complicated.

Therefore, in order to make prevention of complication of the process and increase in spontaneous polarization of the PZT film compatible, it can be said to be more preferable to orient the Pt film strongly in the [222] direction, which is easy for the Pt film to orient, than to orient the Pt film in the [200] direction, which is difficult for the Pt film to orient. For this purpose, it is also necessary to intensify the orientation of the Ti film which is the base.

Related arts are disclosed in Patent Document 1 (Japanese Patent Application Laid-open No. 9-53188), and Non-patent Document 1 (Jpn. J. Appl. Phys. Vol. 36 (1997) pp. L154-L157 Part 2, No. 2A, February 1997).

### SUMMARY OF THE INVENTION

An object of the present invention is to provide a manufacturing method of a semiconductor device capable of enhancing orientation intensity of a capacitor bottom electrode with a simple method.

As a result of repeating the earnest study to solve the above described problem, the inventor of the present invention has conceived the present invention shown as follows.

In a manufacturing method of a semiconductor device according to the present invention, an insulating film is formed above a semiconductor substrate, and thereafter, a conductive film for a bottom electrode is formed on the insulating film. Next, a ferroelectric film is formed on the conductive film for a bottom electrode. Next, a conductive film for a top electrode is formed on the ferroelectric film. Thereafter, the conductive film for a top electrode, the ferroelectric film, and the conductive film for a bottom electrode are patterned to form a ferroelectric capacitor. At a time of forming the conductive film for a bottom electrode, a lower side layer of the conductive film for a bottom electrode is formed on the insulating film, and thereafter, an upper side layer of the conductive film for a bottom electrode is formed on the lower side layer while a temperature of the semiconductor substrate is kept at 250° C. to 450° C.

### BRIEF DESCRIPTION OF THE DRAWINGS

FIGS. 1A to 1P are sectional views showing a manufacturing method of a semiconductor device according to an embodiment of the present invention in sequence of process steps; and

FIG. 2 is a graph showing relationship between a forming temperature of a Pt film and orientation intensity in the [002] direction of the Pt film.

### DETAILED DESCRIPTION OF THE PREFERRED EMBODIMENTS

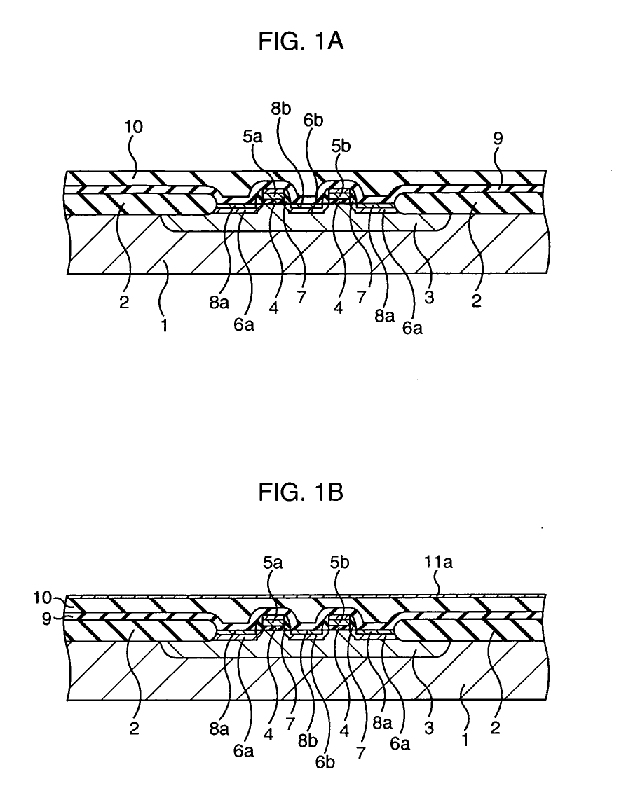

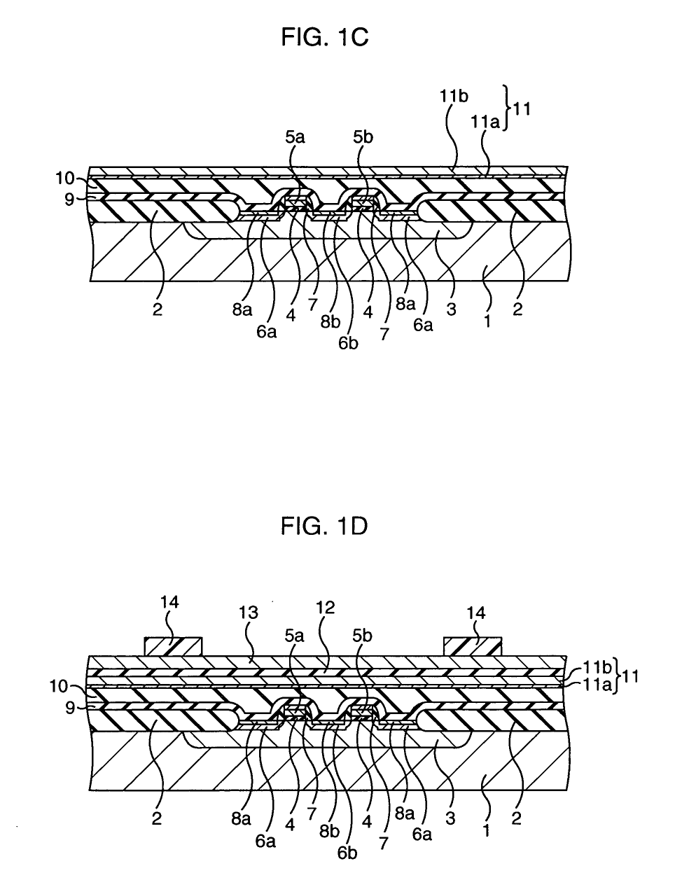

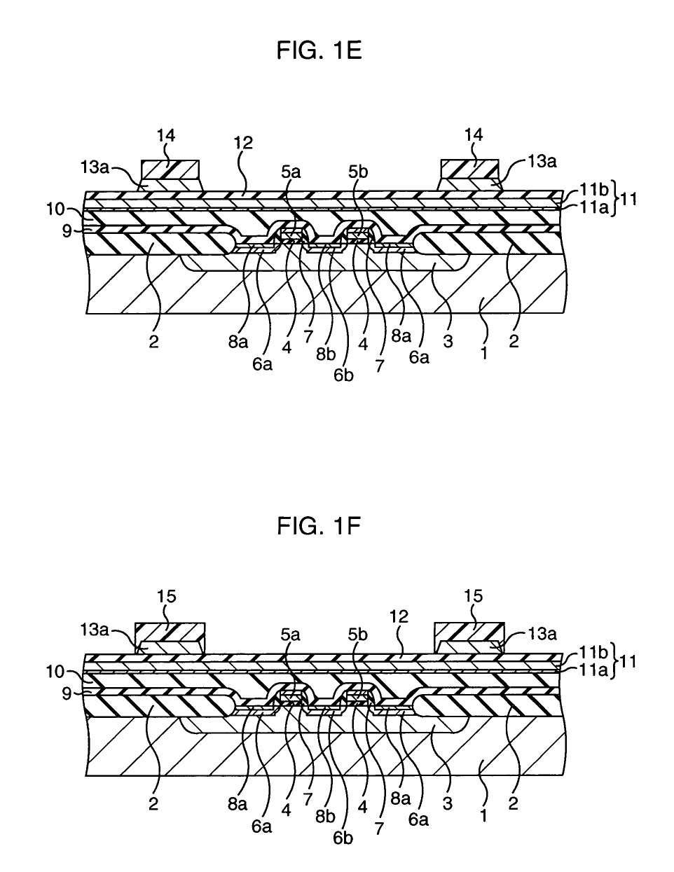

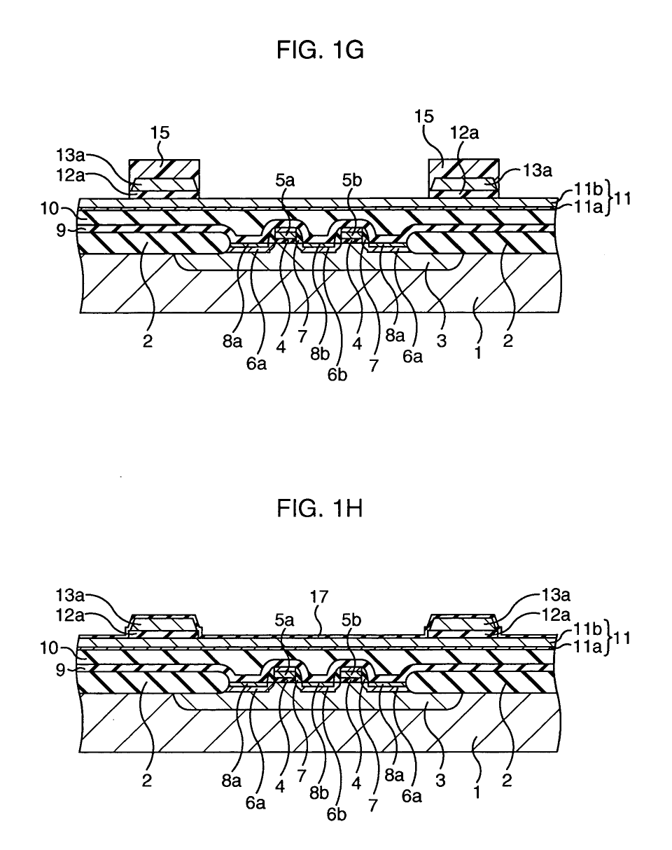

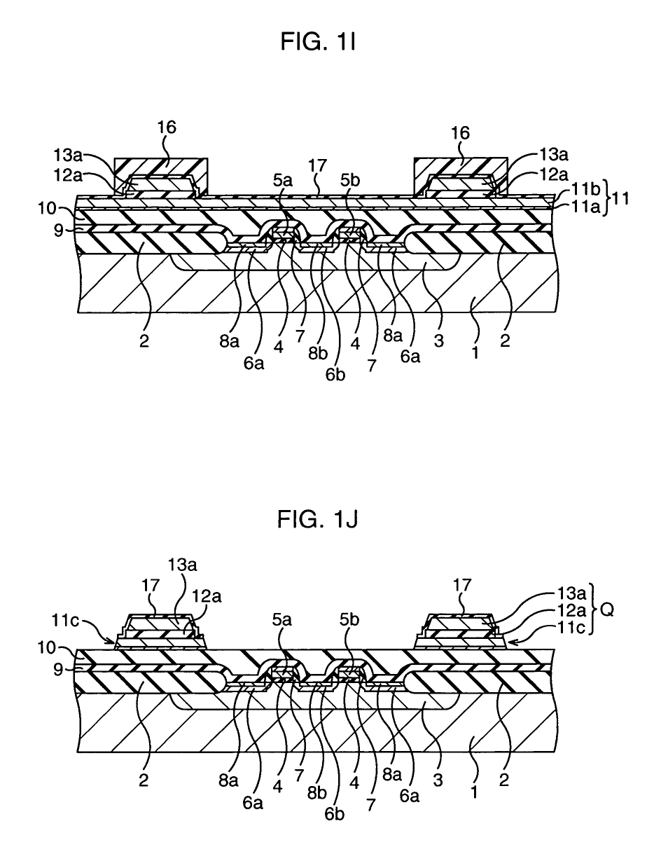

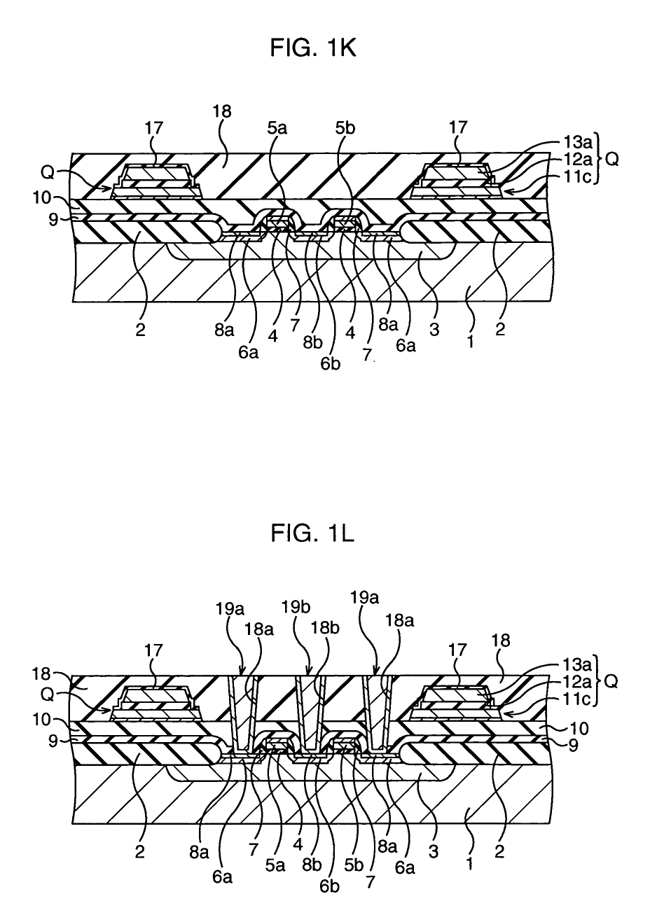

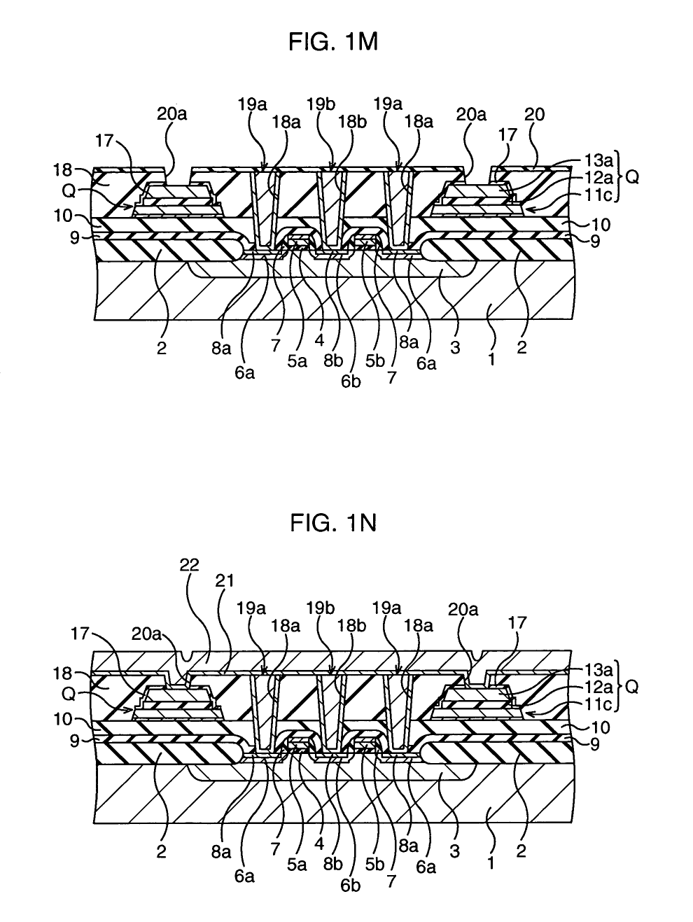

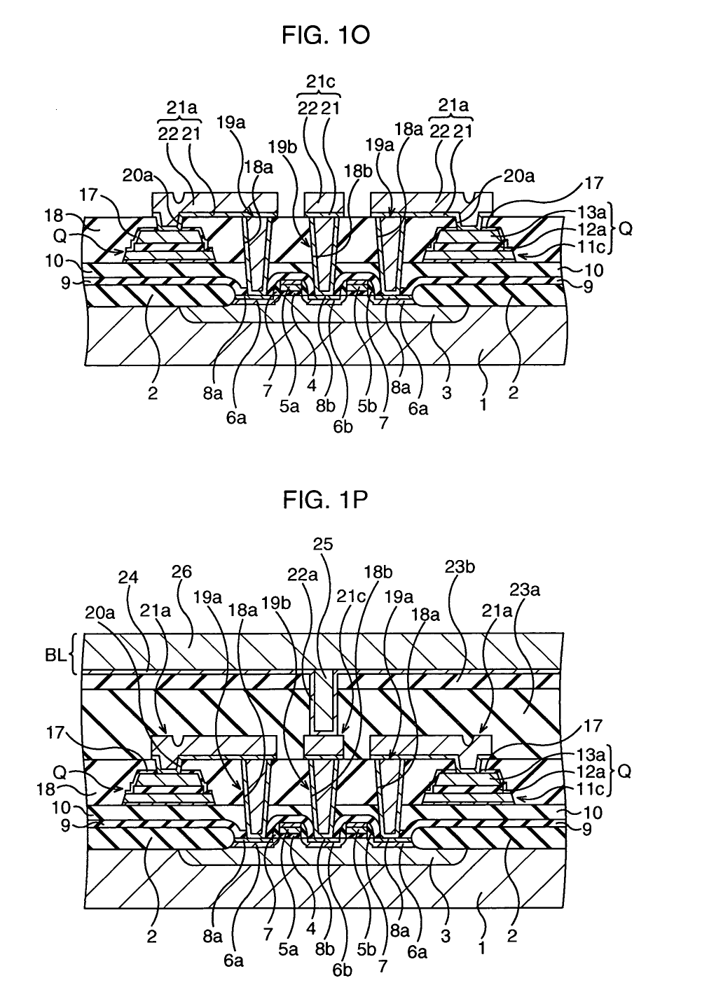

An embodiment of the present invention will now be described in concrete with reference to the accompanying drawings. FIGS. 1A to 1P are sectional views showing a manufacturing method of a semiconductor device according to the embodiment of the present invention in sequence of process steps.

First, as shown in FIG. 1A, an element isolation insulating film 2 is formed on a surface of an n-type or a p-type silicon (semiconductor) substrate 1 by an LOCOS (Local Oxidation of Silicon) method. As a method of forming the element isolation insulating film 2, STI (Shallow Trench Isolation) may be adopted.

After the element isolation insulating film 2 is formed, a p-well 3 is formed in a predetermined active region (transistor forming region) in a memory cell region of the silicon substrate 1.

Thereafter, the surface of the active region of the silicon substrate 1 is thermally oxidized, and a silicon oxidation film is formed as a gate insulating film 4.

Next, a conductive film composed of polycrystalline silicon or refractory metal silicide is formed on an entire surface of an upper side of the silicon substrate 1. Thereafter, the conductive film is patterned into a predetermined shape by a photolithography method, so that gate electrodes 5a and 5b are formed on the gate insulating film 4. The two gate electrodes 5a and 5b are disposed substantially parallel with each other on one p-well 3 in the memory cell region. The gate electrodes 5a and 5b function as a part of a word line.

Subsequently, an n-type impurity is ion-implanted in the p-well 3 at both sides of the gate electrodes 5a and 5b, so that n-type impurity diffusion regions 6a and 6b functioning as source/drains of an n-channel MOS transistor are formed. Further, an insulating film is formed on the entire surface of the silicon substrate 1, and the insulating film is etched back and left as a side wall insulating film 7 at both side portions of the gate electrodes 5a and 5b. As such an insulating film, a silicon oxide (SiO₂) film can be formed by, for example, a CVD method.

Further, by using the gate electrodes 5a and 5b and the side wall insulating film 7 as a mask, an n-type impurity ion is implanted in the well 3 again, and thereby, the n-type impurity diffusion regions 6a and 6b are made to have an LDD (lightly Doped Drain) structure. In one p-well 3, the n-type impurity diffusion region 6b sandwiched by the two electrodes 5a and 5b is to be electrically connected to a bit line, which will be described later, and the two impurity diffusion regions 6a at both sides of the p-well 3 are to be electrically connected to capacitor top electrodes, which will be described later.

As described above, in the p-well 3 in the memory cell region, two n-type MOSFETs are constructed by the gate electrodes 5a and 5b, the n-type impurity diffusion regions 6a and 6b and the like.

Next, a refractory metal film is formed on the entire surface, and the refractory metal film is heated to form refractory metal silicide layers 8a and 8b respectively on the surfaces of the n-type impurity diffusion regions 6a and 6b. Thereafter, the unreacted refractory metal film is removed by wet etching.

Further, by a plasma CVD method, a silicon oxynitride (SiON) film is formed with a thickness of about 200 nm above the entire surface of the silicon substrate 1 as a cover film 9 which covers the MOS transistor. Further, by a plasma CVD method using a TEOS gas, a silicon dioxide (SiO₂) film is formed with a thickness of about 1.0 μm on the cover film 9 as a first interlayer insulating film 10. Subsequently, the first interlayer insulating film 10 is polished by a chemical mechanical polishing (CMP) method to flatten its top surface.

Next, as shown in FIG. 1B, the silicon substrate 1 is placed on a heating stage in a Ti sputtering chamber (not shown), and a temperature of the silicon substrate 1 is increased to a temperature higher than a room temperature (20° C.), for example, to 150° C. and stabilized. The upper limit of the substrate temperature is not especially limited, but is preferably a temperature lower than 300° C.

Further, while the inside of the chamber is evacuated by a vacuum pump (not shown), Ar is supplied into the chamber at a flow rate of 50 sccm as a sputtering gas, and the pressure in the chamber is held at, for example, 3.4×10⁻¹ Pa.

When the atmosphere in the chamber is stabilized, DC power of 2.0 kW is applied to a Ti target, and sputtering of Ti by a DC magnetron sputtering method is started. By keeping this condition for about 15 seconds, a Ti film is formed with a thickness of 5 nm to 50 nm, for example, about 20 nm on the first interlayer insulating film 10. The Ti film is used as a lower side layer 11a of a conductive film for a bottom electrode.

The lower side layer 11a enhances adhesion of a bottom electrode, which will be described later, and the first interlayer insulating film 10, and prevents peeling-off of the bottom electrode from the first interlayer insulating film 10.

As the lower side layer 11a, an alloy film composed of an alloy of Ti and a noble metal may be formed instead of the Ti film. As such an alloy film, for example, a Pt—Ti alloy film, an Ir—Ti alloy film, a Ru—Ti alloy film and the like can be cited.

Thereafter, as shown in FIG. 1C, a Pt film of a thickness of 50 nm to 500 nm, for example, about 175 nm is formed as an upper side layer 11b of the conductive film for a bottom electrode. The forming condition of the Pt film is, for example, DC power of 1.0 kW, an Ar flow rate of 100 sccm, and pressure of 5.0×10⁻¹ Pa. The temperature of the semiconductor substrate 1 is set at 250° C. to 450° C., for example, 350° C. If the thickness of the upper side layer 11b is less than 50 nm, sufficient orientation is not obtained in some cases. On the other hand, if the thickness of the upper side layer 11b exceeds 500 nm, processing sometimes becomes difficult. When the substrate temperature is less than 250° C. or exceeds 450° C., sufficient orientation is hardly obtained.

Thus, the conductive film 11 for a bottom electrode constructed by the lower side layer 11a and the upper side layer 11b is formed on the first interlayer insulating film 10.

As the upper side layer 11b, instead of the Pt film of a single layer, a single-layer film or a stacked film composed of any one of Ir (iridium), Ru(ruthenium), Pd (palladium), PtOX (platinum oxide), IrOₓ (iridium oxide), RuOₓ (ruthenium oxide), and PdOₓ (palladium oxide), or an alloy of them may be formed.

Next, the silicon substrate 1 is placed on a heating stage in a sputtering chamber (not shown) for PZT ((Pb(Zr,Ti)O₃), and the silicon substrate 1 is heated to about 50° C. Then, Ar for sputtering is supplied into the chamber at a flow rate of 15 to 25 sccm, and the inside of the chamber is exhausted by a vacuum pump. When the pressure inside the chamber is stabilized, RF power of a frequency of 13.56 MHz and power of 1.0 kW is applied to the PZT target, and thereby, a PZT film as a ferroelectric film 12 is formed as shown in FIG. 1D, with a thickness of 150 nm to 200 nm, for example, about 175 nm on the conductive film 11 for a bottom electrode by an RF sputtering method.

The amount of Pb in the ferroelectric film 12 is controllable by regulating the flow rate of Ar used for sputtering. The forming method of the ferroelectric film 12 is not limited to the sputtering method, but may be a spin-on method, a sol-gel method, an MOD (Metal Organic Deposition) method, or an MOCVD (Metal Organic CVD) method. Further, in accordance with the required characteristics of the capacitor, PZT which composes the ferroelectric film 12 may be doped with a small amount of Ca (calcium), Sr (strontium), La (lanthanum) and the like.

As the material composing the ferroelectric film 12, a Bismuth layer structured compound such as SrBi₂ (TaₓNb₁₋ₓ)₂O₉(o<x≦1) and Bi₄Ti₂O₁₂, SrTiO₃, (Ba,Sr)TiO₃, (Pb,La) (Zr,Ti)O₃, and the like are cited other than PZT.

Thereafter, the ferroelectric film 12 is annealed in the atmosphere containing oxygen, and thereby, PZT which composes the ferroelectric film 12 is crystallized. In this annealing, for example, RTA (Rapid Thermal Annealing) of two steps is adopted. In the first step, annealing is performed in the condition of, for example, a substrate temperature of 600° C., and treatment time of 90 seconds under the Ar atmosphere of an oxygen concentration of 2.5%. In the second step, annealing is performed in the conditions of, for example, a substrate temperature of 750° C. and treatment time of 60 seconds under the atmosphere of an oxygen concentration of 100%.

Subsequently, by a DC magnetron sputtering method of two steps, an IrOₓ layer is formed to a thickness of about 200 nm on the ferroelectric film 12 as a conductive film 13 for a top electrode. As the conditions of the first step, for example, the DC power is 1.04 kW, the Ar flow rate is 100 sccm, the O₂ flow rate is 100 sccm, the substrate temperature is 20° C., and the forming time is 29 seconds. As the conditions of the second step, for example, the DC power is 2.05 kW, the Ar flow rate is 100 sccm, the O₂ flow rate is 100 sccm, the substrate temperature is 20° C., and the forming time is 22 seconds.

As a conductive film 13 for a top electrode, a platinum film or a strontium ruthenate (SRO) film may be formed by a sputtering method.

Thereafter, resist is coated on the conductive film 13 for a top electrode, and this is exposed and developed, whereby, first resist patterns 14 each in the shape of a top electrode are formed.

Next, as shown in FIG. 1E, the first resist patterns 14 are used as a mask, and the conductive film 13 for a top electrode is etched. As a result, the remaining conductive film 13 for a top electrode is used as capacitor top electrodes 13a.

The first resist patterns 14 are removed, and in the condition of the temperature of 650° C. and 60 minutes, the ferroelectric film 12 is annealed under the oxygen atmosphere by being transmitted through the capacitor top electrodes 13a. The annealing is performed for restoring the ferroelectric film 12 from the damage caused at the time of sputtering and etching.

Next, resist is coated on the capacitor top electrodes 13a and the ferroelectric film 12, and this is exposed and developed, whereby second resist patterns 15 are formed as shown in FIG. 1F.

Thereafter, as shown in FIG. 1G, the second resist patterns 15 are used as a mask, the ferroelectric film 12 is etched. As a result, the remaining ferroelectric films 12 are used as capacitor ferroelectric films 12a.

The second resist patterns 15 are removed, and in the condition of a temperature of 650° C. and 60 minutes, the capacitor ferroelectric films 12a are annealed under an oxygen atmosphere.

Further, as shown in FIG. 1H, an Al₂O₃ film is formed with a thickness of about 50 nm on the capacitor top electrodes 13a, the capacitor ferroelectric film 12a and the conductive film 11 for a bottom electrode as an encapsulation layer 17 at a room temperature by a sputtering method. The encapsulation layer 17 is formed for protecting the capacitor ferroelectric film 12a, which is easily reduced, from hydrogen. As the encapsulation layer 17, a PZT film, a PLZT film or a titanium oxide film may be formed.

Thereafter, under an oxygen atmosphere, in the condition of 700° C., 60 seconds, and the rate of temperature rise of 125° C./sec, the capacitor ferroelectric film 12a under the encapsulation film 17 is subjected to rapid thermal annealing, and its film quality is improved.

Next, as shown in FIG. 1I, resist is coated on the encapsulation layer 17, and this is exposed and developed, whereby, third resist patterns 16 in the shape of capacitor bottom electrode shapes are formed above the capacitor ferroelectric films 12a.

Thereafter, as shown in FIG. 1J, the third resist patterns 16 are used as a mask, the encapsulation layer 17 and the conductive film 11 for a bottom electrode layer are etched. As a result, the remaining conductive films 11 for a bottom electrode are used as capacitor bottom electrodes 11c. Next, the third resist patterns 16 are removed.

In this manner, ferroelectric capacitors Q each constructed by stacking the capacitor bottom electrode 11c, the capacitor ferroelectric film 12a and the capacitor top electrode 13a in sequence in layer are formed on the first interlayer insulating film 10.

Subsequently, under an oxygen atmosphere, in the condition of the temperature of 650° C. and 60 minutes, the capacitor ferroelectric films 12a are annealed and restored from damage.

Next, as shown in FIG. 1K, an SiO₂ film of a film thickness of about 1200 nm is formed on the ferroelectric capacitors Q and the first interlayer insulating film 10 as a second interlayer insulating film 18 by a CVD method. Then, the surface of the second interlayer insulating film 18 is flattened by a CMP method. In growth of the second interlayer insulating film 18, as a reactive gas, silane (SiH₄) may used, or TEOS may be used. Flattening of the surface of the second interlayer insulating film 18 is performed until the thickness becomes 200 nm from the top surface of the capacitor top electrode 13a, for example.

Next, as shown in FIG. 1L, the first interlayer insulating film 10, the second interlayer insulating film 18, and the cover film 9 are patterned, so that contact holes 18a and 18b are formed above the n-type impurity diffusion layers 6a and 6b. As an etching gas for the first and second interlayer insulating films 10 and 18 and the cover film 9, a CF-type gas, for example, a mixture gas which is prepared by adding Ar to CF₄, is used.

Next, a titanium (Ti) film is formed with a thickness of 20 nm, and a titanium nitride (TiN) film is formed with a thickness of 50 nm on the surface of the second interlayer insulating film 18 and the inner surfaces of the contact holes 18a and 18b by a sputtering method, as an adhesive layer. Further, by a CVD method using a mixture gas of a tungsten fluoride gas (WF₆), argon, and hydrogen, a tungsten film is formed on the adhesive layer, and thereby, each of the contact holes 18a and 18b is completely filled.

Further, the tungsten film and the adhesive layer on the second interlayer insulating film 18 are removed by a CMP method, and are left only in each of the contact holes 18a and 18b. The tungsten films and the adhesive layers in the contact holes 18a and 18b are used as conductive plugs 19a and 19b.

The first conductive plug 19b above the n-type impurity diffusion region 6b at the center which is sandwiched by the two gate electrodes 5a and 5b in one p-well 3 of the memory cell region is to be electrically connected to a bit line, which will be described later. Two conductive plugs 19a at both sides thereof are to be electrically connected to the capacitor top electrodes 13a via wiring, which will be described later.

Thereafter, the second interlayer insulating film 18 is heated at a temperature of 390° C. in a vacuum chamber, and water is released outside.

Next, as shown in FIG. 1M, an SiON film is formed with a thickness of, for example, 100 nm as an oxidation preventing film 20 on the second interlayer insulating film 18 and the conductive plugs 19a and 19b by a plasma CVD method. The SiON film is formed by using a mixture gas of silane (SiH₄) and N₂O.

Subsequently, photoresist (not shown) is coated on the oxidation preventing film 20, and this is exposed and developed to form windows on the capacitor top electrodes 13a. Then, the photoresist is used as a mask, the encapsulation layer 17, the second interlayer insulating film 18 and the oxidation preventing film 20 are etched. As a result, contact holes 20a are formed above the capacitor top electrodes 13a.

Then, after the photoresist (not shown) is removed, under the condition of 550° C. and 60 minutes, the capacitor ferroelectric film 12a is annealed under the oxygen atmosphere, so that the film quality of the capacitor ferroelectric film 12a is improved. In this case, oxidation of the conductive plugs 19a and 19b is prevented by the oxidation preventing film 20.

Next, as shown in FIG. 1N, the oxidation preventing film 20 is dry-etched by using a CF-type gas and removed.

Thereafter, a titanium nitride (TiN) film is formed on the second interlayer insulating film 18, the conductive plugs 19a and 19b and the inner surfaces of the contact holes 20a as a base conductive film 21 by sputtering. The base conductive film 21 functions as a barrier film having favorable adhesion to an aluminum film, which will be described later. The composing material of the base conductive film 21 is not limited to the titanium nitride, but may be a stacked structure of titanium nitride and titanium, or may be tungsten nitride.

Then, an aluminum film 22 is formed on the base conductive layer 21 by sputtering. The aluminum film 22 is formed to be about 500 nm on the second interlayer insulating film 18. The aluminum film 22 may contain copper.

Subsequently, as shown in FIG. 10, by patterning the aluminum film 22 and the base conductive film 21 by a photolithography method, a via contact pad 21c is formed on the conductive plug 19b at the center of the p-well 3, and top electrode lead-out wirings 21a which are connected to the top surfaces of the capacitor top electrodes 13a through the contact holes 20a from the top surfaces of the conductive plugs 19a at both sides of the conductive plug 19b are formed.

Thus, the capacitor top electrodes 13a are electrically connected to the n-type impurity diffusion regions 6a both sides of the p-well 3 via the top electrode lead-out wirings 21a, the conductive plugs 19a and the refractory metal silicide layers 8a.

As sputtering for forming the base conductive film 21 and the aluminum film 22, long through spattering may be used.

Next, as shown in FIG. 1P, an SiO₂ film is formed with a thickness of about 2300 nm as a third interlayer insulating film 23a by a plasma CVD method using TEOS as a source. As a result, the second interlayer insulating film 18, the top electrode lead-out wirings 21a, and the contact pad 21c are covered with the third interlayer insulating film 23a. Subsequently, the surface of the third interlayer insulating film 23a is flattened by a CMP method.

Further, a protection insulating film 23b composed of SiO₂ is formed on the third interlayer insulating film 23a by a plasma CVD method using TEOS. Then, the third interlayer insulating film 23a and the protection insulating film 23b are patterned, so that a hole 22a is formed on the contact pad 21c above the center of the p-well 3 of the memory cell region.

Next, an adhesive layer 24 composed of titanium nitride (TiN) of a film thickness of 90 nm to 150 nm is formed on the top surface of the protection insulating film 23b and the inner surface of the hole 22a by a sputtering method. Thereafter, the substrate temperature is set at about 400° C., and a blanket tungsten film 25 is formed by a CVD method using WF₆ to fill the hole 22a.

Next, the blanket tungsten film 25 is etched back and left only in the hole 22a, and the blanket tungsten film 25 in the hole 22a is used as a conductive plug of the second layer.

Thereafter, a metal film 26 is formed on the adhesive layer 24 and the blanket tungsten film 25 by a sputtering method. Subsequently, the metal film 26 is patterned by a photolithography method, and a bit line BL which is electrically connected to the n-type impurity diffusion region 6b via the conductive plug 25 of the second layer, the contact pad 21c, the conductive plug 19b of the first layer, and the refractory metal silicide layer 8b is formed.

According to the above embodiment, the substrate temperature (forming temperature) at a time of forming the upper side layer 11b is properly specified, and therefore, the upper side layer 11b including orientation in the extremely favorable [222] direction is formed. Therefore, orientation in the [111] direction of the ferroelectric film 12, which is formed directly thereon, also becomes extremely favorable.

In the above described embodiment, the present invention is applied to the ferroelectric capacitor of the planar structure, but the present invention may be applied to a ferroelectric capacitor of a stack structure and the like.

Hereinafter, the experiment conducted by the inventor of the present invention will be described.

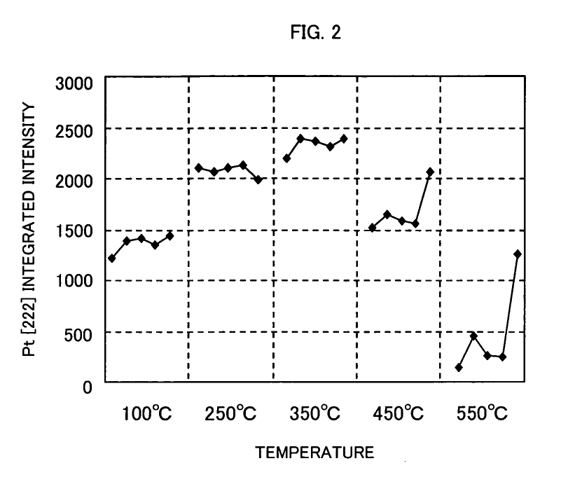

In this experiment, by setting the substrate temperature at the time of forming a Pt film was set at various temperatures, a Pt film was formed with a thickness of 175 nm on a Ti film by a DC magnetron sputtering method. With respect to the sample of each substrate temperature, orientation intensity (integrated intensity) in the [222] direction of the Pt film was measured by an X-ray diffraction method. The result is shown in FIG. 2.

The horizontal axis in FIG. 2 shows the substrate temperature, and the vertical axis shows the orientation intensity (integrated intensity) of the X-ray in the [222] direction of Pt.

As shown in FIG. 2, the orientation intensity in the [222] direction monotonously increases as the substrate temperature rises from 100° C. until the temperature becomes 350° C. On the other hand, when the substrate temperature exceeds 350° C., the orientation intensity monotonously decreases as the temperature rises. In the substrate temperature of 250° C. to 450° C., high orientation intensity was obtained. From the result shown in FIG. 2, it can be said that the substrate temperature is especially preferably set at 250° C. to 400° C.

The experiment result means that in the case where the Pt film is formed at the substrate temperature of 250° C. to 450° C., when the PZT film is formed thereon, and the PZT film is crystallized, the integrated intensity of PZT [222] by the X-ray diffraction is completely led to Pt [222] and the PZT film of a favorable orientation is obtained.

According to the present invention, the substrate temperature at the time of forming the upper side layer of the conductor film for a bottom electrode is properly specified, and therefore, the upper side layer with more intense orientation can be formed. Therefore, the orientation of the ferroelectric film formed thereon can be also made intense, and a ferroelectric capacitor with a large spontaneous polarization amount can be stably manufactured.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A manufacturing method of a semiconductor device, comprising the steps of:
forming an insulating film above a semiconductor substrate;
forming a conductive film for a bottom electrode on said insulating film;
forming a ferroelectric film on said conductive film for a bottom electrode;
forming a conductive film for a top electrode on said ferroelectric film; and
forming a ferroelectric capacitor by patterning said conductive film for a top electrode, said ferroelectric film, and said conductive film for a bottom electrode,
said step of forming said conductive film for a bottom electrode comprising the steps of:
forming a lower side layer of said conductive film for a bottom electrode on said insulating film, and
forming an upper side layer of said conductive film for a bottom electrode on said lower side layer while keeping a temperature of said semiconductor substrate at 250° C. to 450° C.

2. The manufacturing method of a semiconductor device according to claim 1, wherein said upper side layer is formed by a sputtering method.

3. The manufacturing method of a semiconductor device according to claim 1, wherein, as said upper side layer, a conductive layer including at least one kind selected from a group consisting of a platinum layer, an iridium layer, a ruthenium layer, a palladium layer, a platinum oxide layer, an iridium oxide layer, a ruthenium oxide layer and a palladium oxide layer is formed.

4. The manufacturing method of a semiconductor device according to claim 3, wherein an orientation direction of said upper side layer is a [222] direction.

5. The manufacturing method of a semiconductor device according to claim 1, wherein as said lower side layer, a titanium layer or an alloy layer of titanium and a noble metal is formed.

6. The manufacturing method of a semiconductor device according to claim 5, wherein an orientation direction of said lower side layer is a [002] direction.

7. The manufacturing method of a semiconductor device according to claim 1, wherein, as the ferroelectric film, a film of one kind selected from a group constituted of Pb(Zr,Ti)O₃, (Pb,La)(Zr,Ti)O₃, SrTiO₃, (Ba,Sr)TiO₃, and SrBi₂(TaₓNb₁₋ₓ)₂O₉ (0<x≦1), or a film composed of a material made by introducing at least one kind selected from a group consisting of calcium, strontium, and lanthanum into Pb(Zr,Ti)O₃ is formed.

8. The manufacturing method of a semiconductor device according to claim 7, wherein an orientation direction of said ferroelectric film is a [111] direction.

9. The manufacturing method of a semiconductor device according to claim 1, wherein a thickness of said upper side layer is set at 50 nm to 500 nm.

10. The manufacturing method of a semiconductor device according to claim 1, wherein, at a time of forming said upper side layer, said temperature is kept at 250° C. to 400° C.

11. The manufacturing method of a semiconductor device according to claim 1, further comprising the step of crystallizing said ferroelectric film by performing annealing of said ferroelectric film, between said step of forming a ferroelectric film and said step of forming a conductive film for a top electrode.

12. The manufacturing method of a semiconductor device according to claim 11, wherein as said annealing, a first annealing in an Ar atmosphere including oxygen and a second annealing in an oxygen atmosphere are successively performed.
